(19) United States
(12) Patent Application Publication
(10) Pub. No.: US 2008/0309367 A1
(43) Pub. Date: Dec. 18, 2008

(54) SEMICONDUCTOR INTEGRATED DEVICE

(75) Inventor: Kenjirou Matoba, Miyazaki (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Minato-ku (JP)

(21) Appl. No.: 12/115,691

(22) Filed: May 6, 2008

(30) Foreign Application Priority Data
Jun. 15, 2007 (JP) 2007158783

(51) Int. Cl. H03K 19/00

(52) U.S. Cl. 326/16

(57) ABSTRACT

A semiconductor integrated device includes an internal oscillation circuit that oscillates to output a clock signal, a logic circuit, and a control circuit. In a normal operation mode, the logic circuit loads a target data signal in synchronization with the clock signal, and in a test mode, the logic circuit outputs a stop signal for stopping supply of the clock signal at a predetermined time, and allows the target data signal to be transferred to and from the outside after the stop signal is outputted. The control circuit controls such that, in the normal operation mode, the clock signal is supplied to the logic circuit, and in the test mode, the clock signal is not supplied to the logic circuit after the stop signal is outputted.

### CROSS-REFERENCE TO RELATED APPLICATION

This application claims priority under 35 USC 119 from Japanese Patent Application No. 2007-158783, the disclosure of which is incorporated by reference herein.

### BACKGROUND OF THE INVENTION

1. Field of the Invention

The present invention relates to a semiconductor integrated device having an internal oscillation circuit.

2. Description of the Related Art

In a Large Scale Integration (LSI) that operates in an internal oscillation circuit, conventionally, a test clock terminal as shown in FIG. 8 is provided in the LSI, and an output from the internal oscillation circuit is used as a clock for a logic circuit in the LSI at the time of normal operation. During a logic test, an external clock inputted via the test clock terminal is used. Thus, different clocks are used at the time of normal operation and testing operation, respectively (for example, see Japanese Patent Application Laid-Open (JP-A) No. 2000-81466).

The external clock is used at the time of testing since a clock frequency outputted from an internal oscillation circuit varies for each sample and it is difficult to determine a width of a clock when preparing a test pattern (TP). Use of an external clock facilitates preparation of TP for a tester. However, in an LSI having a small number of terminals, such as a hole IC, it is not possible to newly provide a terminal for inputting an external clock, whereby it is difficult to create a mode that allows an operation using the external clock.

### SUMMARY OF THE INVENTION

In consideration of the above fact, the present invention provides a semiconductor integrated device in which a logic test can be performed without providing any external clock terminal exclusively used for testing in a test mode of the semiconductor integrated device that operates in an internal oscillation circuit.

One aspect of the present invention is a semiconductor integrated device, including: an internal oscillation circuit that oscillates to output a clock signal; a logic circuit that, in a normal operation mode, loads a target data signal in synchronization with the clock signal, and in a test mode, outputs a stop signal for stopping supply of the clock signal at a predetermined time, and allows the target data signal to be transferred to and from the outside after the stop signal is outputted; and a control circuit that, in the normal operation mode, controls such that the clock signal is supplied to the logic circuit, and in the test mode, controls such that the clock signal is not supplied to the logic circuit after the stop signal is outputted.

Due to the above structure, in the test mode, supply of the clock signal outputted from the internal oscillation circuit to the logic circuit is automatically stopped. Therefore, data transfer can be carried out at any time during a period that the supply of the clock signal is stopped.

As a result, a logic test can be performed if there are at least an input terminal for inputting a switching signal for switching the operation between the normal operation mode and the test mode, and a transfer terminal for transferring a data signal to and from the outside in the test mode. Therefore, a terminal for inputting an external clock signal becomes unnecessary.

The data transfer performed in the test mode may be input of data from the outside to the logic circuit, or may be output of data from the logic circuit to the outside. In the former case, the predetermined time may be a time before the logic circuit loads the target data signal. In the latter case, the predetermined time may be a time after the logic circuit loads the target data signal.

In the above aspect, the logic circuit may further output a restart signal for restarting supply of the clock signal after completion of the transfer of the data signal in the test mode, and the control circuit may further controls such that supply of the clock signal to the logic circuit is restarted after the restart signal is outputted in the test mode.

Due to the above structure, the supplying of the clock signal from the internal oscillation circuit to the logic circuit is automatically restarted.

In the above aspect, in the test mode, an external signal containing the target data signal and the timing signal may be inputted from the outside, a separation circuit may further provided which separates the input external signal into a data signal and a timing signal, and the logic circuit may input, in the test mode, the separated target data signal in synchronization with the separated timing signal.

Due to the above structure, the data signal can be inputted in synchronization with the timing signal contained in the external signal, thereby enabling to easily set a frequency of data transfer at an external end.

### BRIEF DESCRIPTION OF THE DRAWINGS

Exemplary embodiments of the present invention will be described in detail based on the following figures, wherein:

FIG. 1 is a circuit diagram showing a semiconductor integrated device according to a first exemplary embodiment of the present invention;

FIG. 2A is a diagram showing a structure of a serial input circuit, and FIG. 2B is a timing chart that illustrates the function of the serial input circuit;

FIG. 3A is a timing chart of signals used in a normal operation mode of the first embodiment, and FIG. 3B is a timing chart of signals used in a test mode;

FIG. 4 is a diagram showing one example of TP;

FIG. 5 is a circuit diagram showing a semiconductor integrated device according to a second exemplary embodiment of the present invention;

FIG. 6A is a timing chart of signals used in a normal operation mode of the second embodiment, and FIG. 6B is a timing chart of signals used in a test mode;

FIG. 7 is a diagram showing one example of TP; and

FIG. 8 is a diagram showing a structure of a conventional semiconductor integrated device.

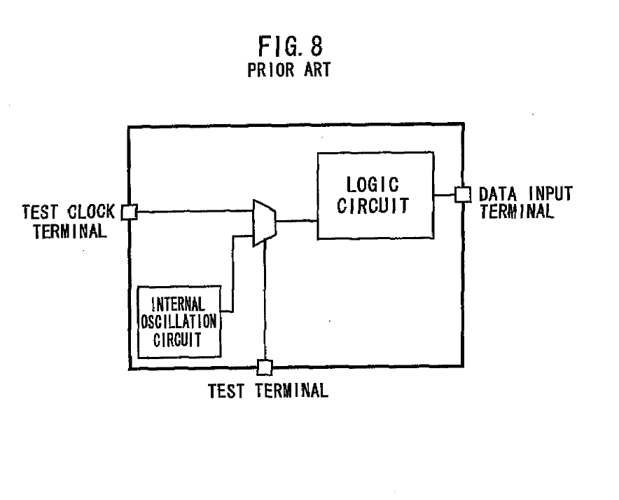

### DETAILED DESCRIPTION OF THE INVENTION

Exemplary embodiments of the present invention will be hereinafter described in detail with reference to the attached drawings.

### First Embodiment

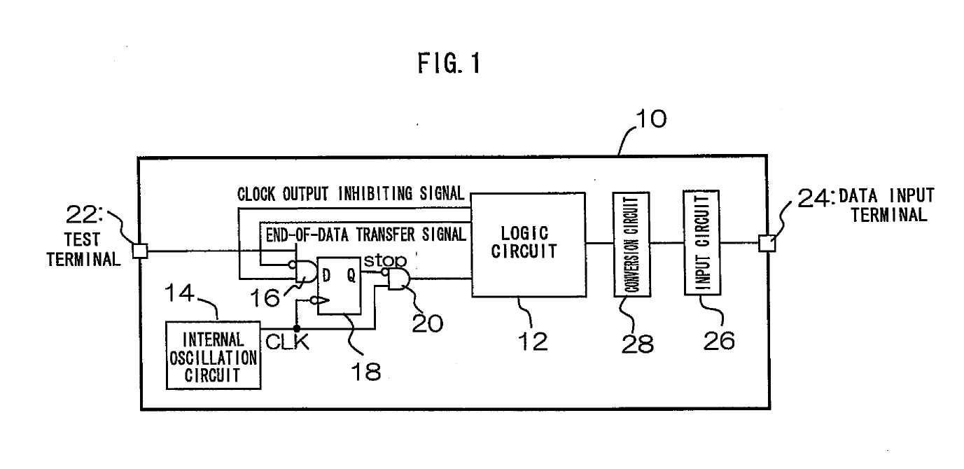

FIG. 1 is a circuit diagram showing a semiconductor integrated device according to the first embodiment. The semiconductor integrated device 10 includes a logic circuit 12, an internal oscillation circuit 14, a first AND circuit 16, a DFF (D flip-flop) circuit 18, a second AND circuit 20, a test terminal 22, a data input terminal 24, a serial input circuit 26, and a serial/parallel conversion circuit 28. A circuit structured by the first AND circuit 16, the DFF 18 and the second AND circuit 20 corresponds to a control circuit of the present invention.

The logic circuit 12 is a circuit that is designed to latch (take in) internal data at predetermined time. The logic circuit 12 operates, in the normal operation mode, in synchronization with a clock signal generated in the internal oscillation circuit 14. In the test mode, the logic circuit 12 operates in a state in which input of the clock signal generated in the internal oscillation circuit 14 is stopped. Further, the logic circuit 12 is designed in such a manner that, in the test mode, one clock's duration of a clock output inhibiting (prohibiting) signal is outputted for one clock prior to the time of data latch. The clock output inhibiting signal is a signal for inhibiting supply of a clock from the internal oscillation circuit 14 to the logic circuit 12. Further, the logic circuit 12 is designed in such a manner that, when data input from the outside is completed during the test mode, an end-of-data transfer signal that indicates the completion of data transfer is outputted.

The first AND circuit 16 is a three-input AND circuit including two positive-phase input terminals and one reverse-phase input terminal. One of the positive-phase input terminals of the first AND circuit 16 is connected to the logic circuit 12, and the clock output inhibiting signal is inputted thereto from the logic circuit 12.

The other positive-phase input terminal of the first AND circuit 16 is connected to a test terminal 22 of the semiconductor integrated device 10. At the time of normal operation, a signal of a low (L) level is inputted from the outside to this positive-phase input terminal, and at the time of test mode, a signal of a high (H) level is inputted from the outside to the positive-phase input terminal.

Further, the reverse-phase input terminal of the first AND circuit 16 is connected to the logic circuit 12, and the end-of-data transfer signal is inputted thereto from the logic circuit 12.

Moreover, the output terminal of the first AND circuit 16 is connected to a D input terminal of the DFF 18.

A clock signal (CLK) outputted from the internal oscillation circuit 14 is inputted to the clock terminal of the DFF 18.

Further, a Q output terminal of the DFF 18 is connected to the second AND circuit 20. Outputted from the Q output terminal of the DFF 18 is a stop signal that controls supply of the clock signal from the internal oscillation circuit 14 to the logic circuit 12.

The second AND circuit 20 is a two-input AND circuit including a positive-phase input terminal and a reverse-phase input terminal. The reverse-phase input terminal of the second AND circuit 20 is connected to the Q output terminal of the DFF 18. The positive-phase input terminal of the second AND circuit 20 is connected to the internal oscillation circuit 14, and the clock signal (CLK) outputted from the internal oscillation circuit 14 is inputted thereto.

The output terminal of the second AND circuit 20 is connected to the logic circuit 12, and when the stop signal is set at the L level, a signal outputted from the output terminal of the second AND circuit 20 is used as a clock signal of the logic circuit 12.

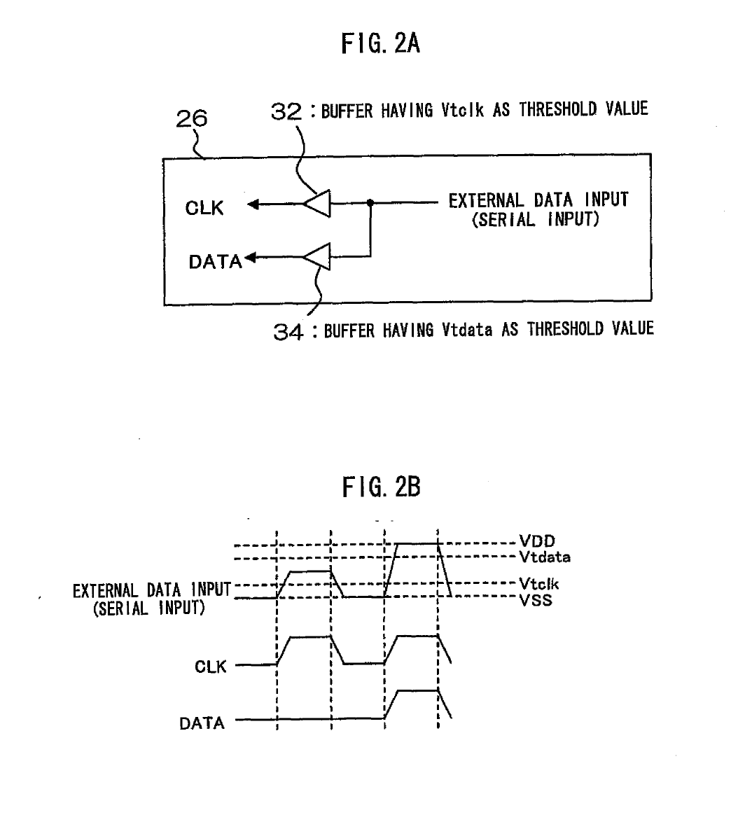

The serial input circuit 26 and the serial/parallel conversion circuit 28 are provided between the logic circuit 12 and the data input terminal 24. The serial input circuit 26 is a circuit that separates serial data inputted from the outside via the data input terminal 24 into a clock signal and a data signal. FIG. 2A shows a structural view of the serial input circuit 26.

The serial input circuit 26 is a single-line serial input circuit, and includes a buffer 32 in which a predetermined voltage value Vtclk is set as a threshold value, and a buffer 34 in which a predetermined voltage value Vtdata is set as a threshold value. The threshold values have the relationship of Vtclk<Vtdata.

As shown in FIG. 2B, a serial external data signal inputted from the outside includes a clock signal in which the voltage value is set between the threshold value Vtclk and the threshold value Vtdata, and a data signal (also serving as the clock signal) in which the voltage value exceeds the threshold value Vtdata. When the external data signal is inputted from the input terminal of the serial input circuit 26, it is separated into a clock signal (CLK) and a data signal (DATA) by the buffer 32 and the buffer 34 having the different threshold values, and the separated signals are outputted.

Specifically, when the inputted signal has a voltage value between the threshold value Vtclk and the threshold value Vtdata, only the clock signal (CLK) is outputted. When the inputted signal has a voltage value greater than the threshold value Vtdata, both the clock signal (CLK) and the data signal (DATA) are outputted.

Hereinafter, the clock signal outputted from the internal oscillation circuit 14 will be referred to as an internal clock signal, and the clock signal contained in the external data signal inputted from the outside will be refereed to as an external clock signal, and thus these clock signals will be described distinctively.

The external clock signal and the data signal, which are outputted from the serial input circuit 26 is inputted to the serial/parallel conversion circuit 28 provided at the following stage of the serial input circuit 26. The serial/parallel conversion circuit 28 is formed by shift registers, and sequentially performs parallel conversion of the data signal in synchronization with the inputted external clock signal, and outputs the result of the conversion to the logic circuit 12.

The semiconductor integrated device 10 structured as the above operates as follows.

Firstly, the operation in the normal operation mode will be described. In the normal operation mode, an input signal from the test terminal 22 is set at L level. Thereby, the output of the first AND circuit 16 is maintained at the L level, and a stop signal at L level is outputted from the Q output terminal of the DFF 18 to the reverse-phase input terminal of the second AND circuit 20 in the output intervals of the clock signals outputted from the internal oscillation circuit 14. On the other hand, a clock signal outputted from the internal oscillation circuit 14 is inputted to the positive-phase input terminal of the second AND circuit 20. As a result, the internal clock signal outputted from the internal oscillation circuit 14 is inputted to the logic circuit 12 as a clock signal that is used by the logic circuit 12.

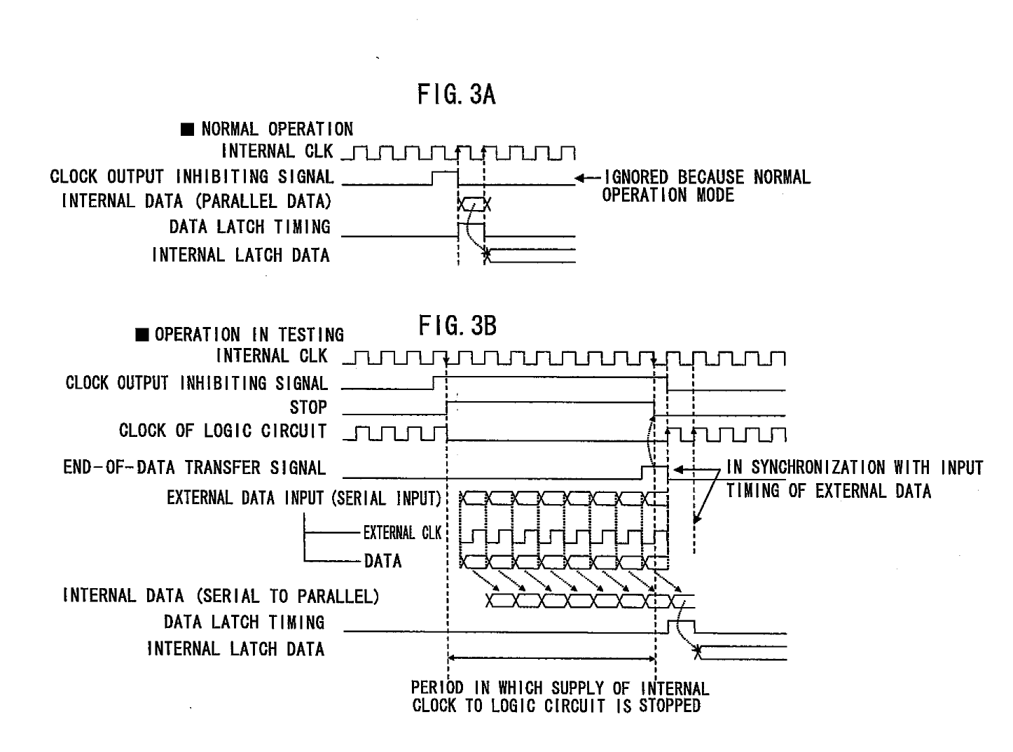

FIG. 3A is a timing chart of signals used in the normal operation mode. The waveform indicated by “internal CLK” is the internal clock signal outputted from the internal oscillation circuit 14. As shown in the drawing, even if the clock output inhibiting signal is outputted from the logic circuit 12, the signal inputted from the test terminal 22 is at the L level, and therefore, the internal clock signals are continuously supplied to the logic circuit 12. The logic circuit 12 latches internal data (parallel data) generated in the internal processing of the logic circuit 12 in synchronization with fall of a data latch timing signal generated in synchronization with the internal clock signal. In this case, the data latch timing signal is designed so as to be generated within the logic circuit 12 at a predetermined time.

Next, the operation in the test mode will be described. FIG. 3B is a timing chart of signals used in the test mode. Further, FIG. 3B shows a timing chart when 8-bit external data is inputted by a serial transfer method.

In the test mode, an input signal from the test terminal 22 is set at the H level. Further, as described above, the clock output inhibiting signal is outputted from the logic circuit 12 (i.e., the signal becomes the H level) from one clock before data latch timing, in which the logic circuit 12 latches the internal data. Therefore, the output signal of the first AND circuit 16 is maintained at the H level. As a result, a stop signal of H level is outputted from the Q output terminal of the DFF 18 to the reverse-phase input terminal of the second AND circuit 20. As shown in FIG. 3B, the stop signal rises to the H level when the internal clock signal falls directly after the build-up of the clock output inhibiting signal.

On the other hand, the internal clock signal outputted from the internal oscillation circuit 14 is inputted to the positive-phase input terminal of the second AND circuit 20, while the signal of H level outputted from the DFF 18 is inputted to the other input terminal (at the reverse-phase input terminal) and is inverted so as to be L level. As a result, output from the second AND circuit 20 is inhibited. Thereby, input of the clock signal from the internal oscillation circuit 14 to the logic circuit 12 is brought into a stopped state. A waveform indicated by “clock of logic circuit” is a waveform that shows the state of how the internal clock signal is supplied to the logic circuit 12. As shown in this drawing, when the stop signal becomes the H level, the supply of the internal clock signal to the logic circuit 12 is stopped.

Next, at a given time that is set at the external end, a serial data signal is inputted from the outside (external end) via the data input terminal 24. The signal inputted from the outside to the semiconductor integrated device 10 is generated so as to contain both information of the external clock signal (CLK) and the data signal (DATA). More specifically, the external clock signal is generated by, as shown in FIG. 2, generating and outputting a signal having a voltage value between a threshold value Vtclk and a threshold value Vtdata at a predetermined frequency. Further, the data signal is generated by, instead of the external clock signal of the predetermined frequency, generating and outputting a data signal whose voltage value is larger than the threshold value Vtdata at the same time as that of the external clock signal (i.e., the data signal is superposed on the external clock signal).

When the serial signal as above is inputted from the outside to the serial input circuit 26 via the data input terminal 24, the two buffers 32 and 34 separate the serial signal into the external clock signal and the data signal. Further, the serial/parallel conversion circuit 28 performs parallel conversion of the data signal separated from the serial data signal, and outputs the data signal subjected to the parallel conversion, and the external clock signal to the logic circuit 12.

When data transfer from the outside to the semiconductor integrated device 10 is completed, an end-of-data transfer signal (H level) is outputted from the logic circuit 12 to the reverse-phase input terminal of the first AND circuit 16. This will be an input of a signal of L level to the first AND circuit 16, and the output of the second AND circuit 20 also becomes L level. The DFF 18 loads the output signal of L level from the first AND circuit 16 when the internal clock signal from the internal oscillation circuit 14 falls. Thereby, the stop signal outputted from the Q output terminal falls to L level. The stop signal of L level is inverted at the reverse-phase input terminal of the second AND circuit 20 and become an input of H level to the second AND circuit 20. Hence, supplying of the internal clock signal from the internal oscillation circuit 14 to the logic circuit 12 is restarted.

At the time when the supply of the internal clock signal from the internal oscillation circuit 14 to the logic circuit 12 is restarted, the clock output inhibiting signal also becomes L level. Further, at the time when the clock output inhibiting signal becomes L level, a data latch timing signal is outputted (the device is designed such that the data latch timing signal is generated at this timing), and the data signal inputted from the outside is latched as the internal data at this time.

As described above, the semiconductor integrated device 10 is configured such that the supply of the internal clock signal to the logic circuit 12 is automatically stopped at the time when data is required in the device 10, so that the device 10 is set to be a state of waiting for input of the external data signal. Thereafter, the external data signal can be inputted at any timing, and when the input of the signal completes, the supply of the internal clock signal to the logic circuit 12 is automatically restarted. Due to this configuration, in preparing a test pattern (TP), there is no need to set a frequency of one clock for each sample. Further, it is also unnecessary to provide an external clock terminal exclusively used for the test mode.

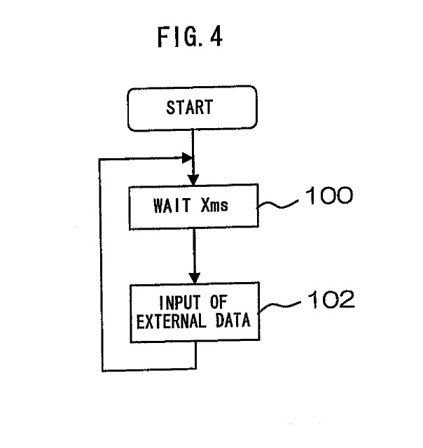

For example, in a case in which data is inputted every ten clocks, a TP as shown in FIG. 4 can be prepared. In step 100, the device 10 waits for time Xms. Note that X indicates a value obtained by multiplying a maximum cycle time (frequency) of the internal clock signal outputted from the internal oscillation circuit 14 by ten (i.e., the maximum cycle time (frequency)×10).

In step 102, input of the external data signal is carried out. Specifically, the serial data signal containing a clock signal having a given frequency as described above is generated as the external data signal, and is inputted to the semiconductor integrated device 10. When the input is completed, the process returns to step 100.

### Second Embodiment

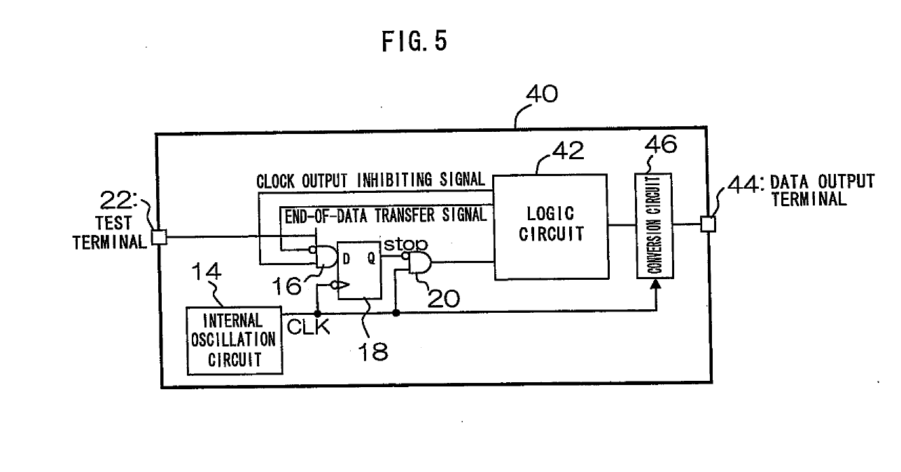

FIG. 5 is a circuitry diagram showing a semiconductor integrated device 40 according to a second embodiment of the present invention. The semiconductor integrated device 40 shown therein includes a logic circuit 42, the internal oscillation circuit 14, the first AND circuit 16, the DFF 18, the second AND circuit 20, the test terminal 22, a data output terminal 44 and a parallel/serial conversion circuit 46.

It should be noted that the components shown in FIGS. 2 and 5 having the same reference numbers correspond to components having the same functions, and therefore, a description thereof will be omitted. Hence, different parts from those of the first embodiment will be described hereinafter.

The semiconductor integrated device 40 of the second embodiment is provided with a data output terminal 44 instead of the data input terminal 24 of the first embodiment. The data output terminal 44 is a terminal that outputs internal data latched in the logic circuit 42, to the outside.

The logic circuit 42 is a circuit that is designed to, in the same manner as the logic circuit 12 of the first embodiment, latch (load) the internal data at a predetermined timing. Further, in the second embodiment, a test mode to monitor the internal data from the outside of the semiconductor integrated device 40 is provided. During the test mode, the logic circuit 42 is designed such that at the time one clock after of the data latch timing, a clock output inhibiting signal is outputted for a period of one clock. Moreover, the logic circuit 42 is designed such that, when output of data to the outside is completed during the test mode, an end-of-data transfer signal that indicates completion of the data transfer is outputted. Incidentally, the internal data signal outputted from the logic circuit 42 during the test mode is a given testing monitor signal that is generated in the logic circuit 42 or is previously set.

Furthermore, a parallel/serial conversion circuit 46 is provided between the logic circuit 42 and the data output terminal 44. A clock signal outputted from the internal oscillation circuit 14 is inputted to the parallel/serial conversion circuit 46. The parallel/serial conversion circuit 46 converts internal data (parallel data) outputted from the logic circuit 42 in synchronization with the clock signal of the internal oscillation circuit 14, to serial data, and outputs the converted serial data.

Next, the operation of the semiconductor integrated device 40 of the second embodiment will be described.

In the normal operation mode, the device operates in the same manner as in the first embodiment, and the internal clock signal outputted from the internal oscillation circuit 14 is inputted as a clock signal that is used in the logic circuit 42 in an unchanged state.

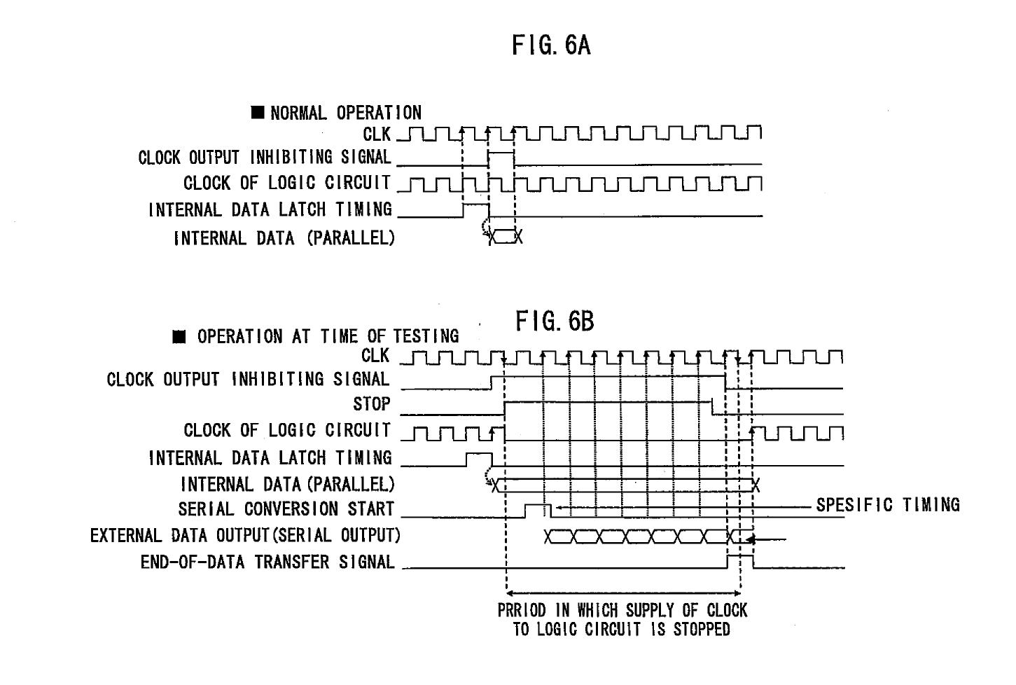

FIG. 6A is a timing chart of signals used in the normal operation mode. The waveform indicated by “CLK” is a clock signal outputted from the internal oscillation circuit 14. In the same manner as in the first embodiment, even if the clock output inhibiting signal is outputted from the logic circuit 42, the signal inputted from the test terminal 22 is constantly L level. Therefore, in synchronization with the internal clock signal, the logic circuit 42 latches the internal data (parallel data) generated in the internal processing of the logic circuit 42 in synchronization when the data latch timing signal falls. Note that the device 40 is designed so that the data latch timing signal is generated within the logic circuit 42 at a predetermined timing.

Next, the operation in the test mode will be described. FIG. 6B is a timing chart of signals used in the test mode. FIG. 6B shows a timing chart in a case in which an 8-bit internal data signal is outputted by a serial transfer method.

In the test mode, the input from the test terminal 22 is set at the H level. Further, as described above, at one clock after the data latch timing when the logic circuit 42 latches the internal data, a clock output inhibiting signal is outputted from the logic circuit 42 (which signal becomes H level). As a result, in the same manner as in the first embodiment, the stop signal becomes H level when the internal clock signal falls directly after the build-up of the clock output inhibiting signal, and supply of the clock signal to the logic circuit 42 is stopped. The waveform indicated by “clock of logic circuit” in FIG. 6B is a waveform that indicates that the clock signal supplied from the internal oscillation circuit 14 to the logic circuit 42. As shown in FIG. 6B, when the stop signal becomes H level, the supply of the clock signal to the logic circuit 42 is stopped.

Subsequently, a serial conversion start signal is generated within the logic circuit 42, and at this time, the internal data latched within the logic circuit 42 is outputted to the parallel/serial conversion circuit 46, and parallel-serial conversion is started. The logic circuit 42 is designed such that the serial conversion starting signal is generated within the logic circuit 42 at a given timing (for example, such that the generation of the serial conversion starting signal is triggered by falling of the stop signal). In other words, the output of the latched internal data to the outside is triggered by the serial conversion starting signal.

When data transfer to the outside is completed, an end-of data transfer signal (H level) is outputted from the logic circuit 42, and in the same manner as in the first embodiment, the supply of the clock signal from the internal oscillation circuit 14 to the logic circuit 42 is restarted.

As described above, in the device 40, at the time when the internal data is latched, the supply of the clock signal to the logic circuit 42 is automatically stopped, the logic circuit 42 waits for the serial conversion starting signal, and thereafter, data output to the outside is started. When the data transfer (output) is completed, the supply of the clock signal to the logic circuit 42 is automatically restarted. For this reason, there is no need to set one clock frequency for each sample when preparing a testing TP. Further, this eliminates necessity of providing an external clock terminal exclusively used for the test mode.

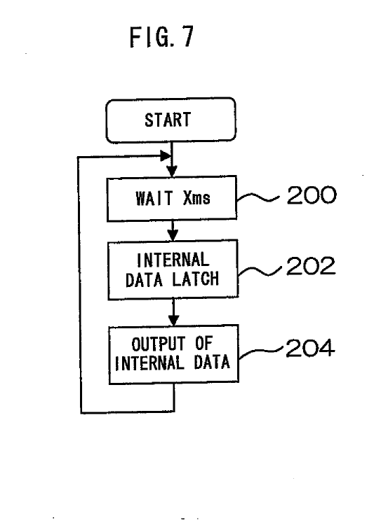

For example, in a case in which data is outputted by ten clocks, a TP as shown in FIG. 7 can be prepared. In step 200, the device waits for time Xms. Note that X indicates a value obtained by multiplying a maximum cycle time (frequency) of the internal clock signal outputted from the internal oscillation circuit 14 by ten (i.e., the maximum cycle time (frequency)×10).

In step 202, the internal data is latched at a given timing. Next, in step 204, the latched internal data is outputted, and the process returns to step 200.

The first embodiment and the second embodiment are described using the circuit structures shown in FIGS. 1 and 5, respectively, by way of example, but the present invention is not limited to the same. Various design modifications could be made within the scope of the invention as recited in the claims of the present application.

For example, the timing at which each of the signals is generated, as described in the embodiments, are examples, and the present invention is not limited to these embodiments.

Further, for example, it is also possible to form a circuit structure having a testing function for both input and output by combining the respective circuit structures of the first and second embodiments. In this case, when the terminal for input of data and the terminal for output of data are shared, a selector can be provided within the semiconductor integrated device and input/output operation can be carried out by switching the selector or the like.

As described above, the present invention allows a semiconductor integrated device that operates in an internal oscillation circuit to perform a logic test in a test mode without providing an external clock terminal exclusively used for testing.

What is claimed is:

1. A semiconductor integrated device comprising:
an internal oscillation circuit that oscillates to output a clock signal;
a logic circuit that, in a normal operation mode, loads a target data signal in synchronization with the clock signal, and in a test mode, outputs a stop signal for stopping supply of the clock signal at a predetermined time, and allows the target data signal to be transferred to and from the outside after the stop signal is outputted; and
a control circuit that, in the normal operation mode, controls such that the clock signal is supplied to the logic circuit, and in the test mode, controls such that the clock signal is not supplied to the logic circuit after the stop signal is outputted.

2. The semiconductor integrated device according to claim 1, wherein the logic circuit further outputs a restart signal for restarting supply of the clock signal after completion of the transfer of the data signal in the test mode, and the control circuit further controls such that supply of the clock signal to the logic circuit is restarted after the restart signal is outputted in the test mode.

3. The semiconductor integrated device according to claim 1, wherein the transfer of the data signal effected in the logic circuit in the test mode is data input from the outside to the logic circuit, and
wherein the predetermined time is a time before the logic circuit loads the target data signal.

4. The semiconductor integrated device according to claim 3, wherein in the test mode, an external signal containing the target data signal and the timing signal is inputted from the outside,
a separation circuit is further provided which separates the input external signal into a data signal and a timing signal, and
the logic circuit inputs, in the test mode, the separated target data signal in synchronization with the separated timing signal.

5. The semiconductor integrated device according to claim 1, wherein the transfer of the data signal effected in the logic circuit in the test mode is data output from the logic circuit to the outside, and
the predetermined time is a time after the logic circuit loads the target data signal.
